(19) United States
(12) Patent Application Publication
(10) Pub. No.: US 2004/0260988 A1
(43) Pub. Date: Dec. 23, 2004

(54) Semiconductor memory, system for testing a memory cell, and method for testing a memory cell

(75) Inventor: Kenji Kobayashi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/747,094

(22) Filed: Dec. 30, 2003

(30) Foreign Application Priority Data
Jun. 20, 2003 (JP) P2003-176555

(51) Int. Cl. G11C 29/00

(52) U.S. Cl. 714/719

(57) ABSTRACT

A semiconductor memory includes a memory cell array, a fail-memory configured to store data for deficient bits, deficient rows, and deficient columns, a comparator configured to compare a value stored in the memory cell with a value of the test vector, and to detect deficient bits, and a deficient row detector configured to compare the number of deficient bits with a first criterion, to detect an address of the deficient rows when the number of deficient bits is larger than the first criterion.

### CROSS REFERENCE TO RELATED APPLICATIONS

This application is based upon and claims the benefit of priority from the prior Japanese Patent Applications No. P2003-176555, filed on Jun. 20, 2003; the entire contents of which are incorporated herein by reference.

### BACKGROUND OF THE INVENTION

1. Field of the Invention

The present invention relates to a semiconductor memory, system for testing a memory cell, and method for testing a memory cell.

2. Description of the Related Art

Semiconductor memories on a LSI have tended to have a larger capacity and be operated faster with the development of microfabrication techniques. However, with larger capacity and high-speed operation, the manufacturing yield of manufactured semiconductor memories has decreased. One of methods for raising the manufacturing yield is to switch from a deficient memory cell to a regular memory cell on the same semiconductor chip. By this method, a fail-bit-map is created and the fail-bit-map is analyzed. Then a row with the deficient cell in a memory cell matrix is switched to the regular memory cells reserved in the memory cell matrix. Moreover, one of semiconductor memories for searching a deficient memory cell in itself includes a circuit detecting the place of the deficient memory cell, a circuit feeding the compressed data for the place by a linear feedback register circuit (LFSR), and a redundant circuit, which can be switched to the deficient cell based on the data.

However, the semiconductor memory compresses the data for all the deficient cells, feeds the compressed data to an external device, and switches the deficient cell to the redundant circuit. Accordingly, a large amount of data for all deficient memory cells should be stored by the semiconductor memory before the data are compressed. The large amount of data requires the capacity of a fail-memory storing the data to be large and the semiconductor memory including the fail-memory to be large. Such a large semiconductor memory dissipates a great deal of electric power. Even if the data is compressed, the large amount of data for all the deficient memory cells requires a long time to be transmitted to the external device. Moreover, the test time is increased with the larger capacity of the fail-memory because only one self-diagnosis circuit in the semiconductor memory, shown in Japanese patent laid open (Kokai) No. 11-16393, searches the deficient memory cells.

### SUMMARY OF THE INVENTION

An aspect of the present invention inheres in a semiconductor memory including a semiconductor memory comprising a memory cell array defined by a matrix of memory cells collocated at each intersection of rows and columns of the memory cells, a fail-memory configured to store data for a deficient bit, a deficient row, and deficient column in the memory cell array, a comparator configured to transmit a test vector to the memory cells by scanning the rows, to compare a value stored in the memory cells with the value of the test vector, and to detect a memory cell as the deficient bit when the value stored in the memory cell differs from the value of the test vector and a deficient row detector configured to compare the number of deficient bits with a first criterion which is larger than one in the row, to detect an address of the row when the number of deficient bits is larger than the first criterion, and to store the data for the deficient bit when the number of deficient bits is not larger than the first criterion.

Another aspect of the present invention inheres in a system for testing a memory cell comprising a pattern generator configured to generate a test vector to a memory cell array which is a matrix of memory cells collocated at each intersection of rows and columns of the memory cells, a compare-instruction unit configured to instruct the pattern generator to transmit the test vector to each of the memory cells by scanning a row, to instruct a semiconductor memory to compare a value stored in the memory cell with a value of the test vector, and instruct the semiconductor memory to detect the memory cell as a deficient bit when the value stored in the memory cell differs from the value of the test vector, a detect-instruction unit configured to instruct the semiconductor memory to compare the number of deficient bits with a first criterion which is larger than one in the row, to instruct the semiconductor memory to detect an address of the row when the number of deficient bits is larger than the first criterion, and to instruct the semiconductor memory to store data for the deficient bit when the number of deficient bits is not larger than the first criterion, and an address fail-memory configured to store the data for the address of the row.

Still another aspect of the present invention inheres in a method for testing a memory cell in a plurality of memory macros, wherein transmitting the test vector to each of memory cells of each of a plurality of memory macros in a memory cell array defined by a matrix of the memory cells collocated at each intersection of rows and columns of the memory cells, comparing a value stored in the memory cells of each of the memory macros with a value of the test vector, detecting the memory cells of each of the memory macros as a deficient bit when the value stored in the memory cells differ from the value of the test vector, counting the number of deficient bits in the row of each of the memory macros, comparing the number of deficient bits in the row of each of the memory macros with first criterion which is larger than one, detecting an address of the row of each of the memory macros as the deficient row when the number of deficient bits in the row is larger than the first criterion, storing data for the deficient bits of each of the memory macros when the number of deficient bits is not larger than the first criterion and transmitting the data of each of the memory macros stored to a tester sequentially.

### BRIEF DESCRIPTION OF THE DRAWINGS

FIG. 1 is a view schematically showing the semiconductor memory of the first embodiment of the present invention.

FIG. 2 is a view schematically showing the memory macro configuring the semiconductor memory of the first embodiment of the present invention.

FIG. 3 is a view schematically showing the deficient bit in the memory cell array.

FIG. 4 is a flowchart schematically showing the test method of the first embodiment of the present invention.

FIG. 5 is a view schematically showing the memory macro in the semiconductor memory of other embodiment of the present invention.

FIG. 6 is a view schematically showing the memory cell array configuring the semiconductor memory of other embodiment of the present invention.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set forth such as specific signal values, etc. to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

(First Embodiment)

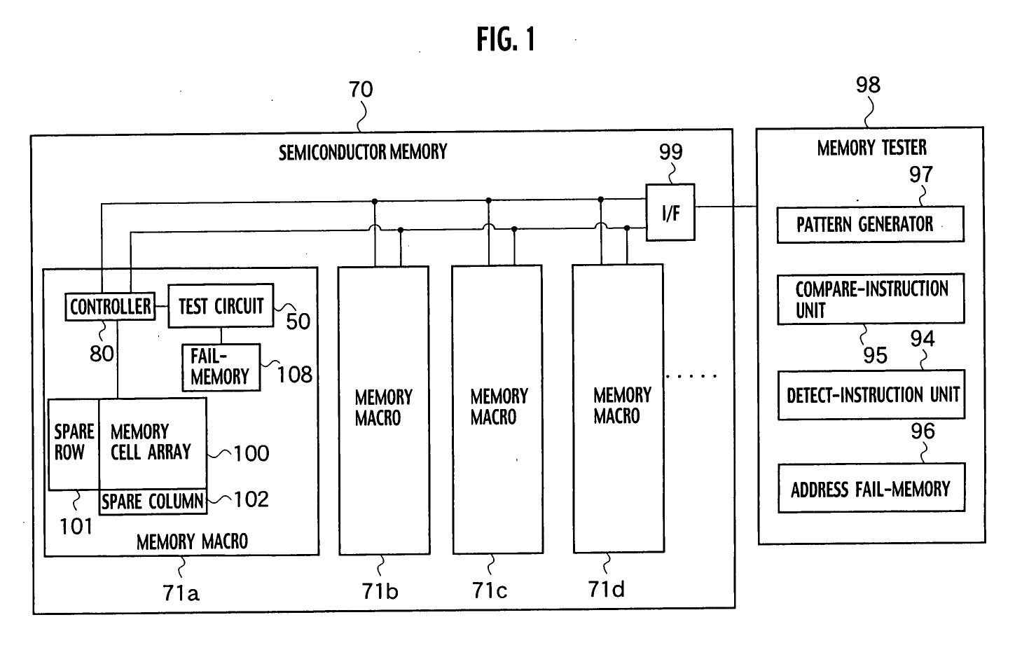

As shown in FIG. 1, a semiconductor memory according to a first embodiment includes an interface 99 connected to a tester 98, and a plurality of memory macros 71a, 71b, 71c, 71d or the like. The memory macro 71a includes a controller 80, a test circuit 50 connected to the controller 80, a memory cell array 100 connected to the controller 80, a spare row connected to the memory cell array 100, a spare column connected to the memory cell array 100, and a fail-memory 108 connected to the test circuit 50. Each of the memory macros 71b, 71c, 71d, or the like has parts similar to the memory macro 71a.

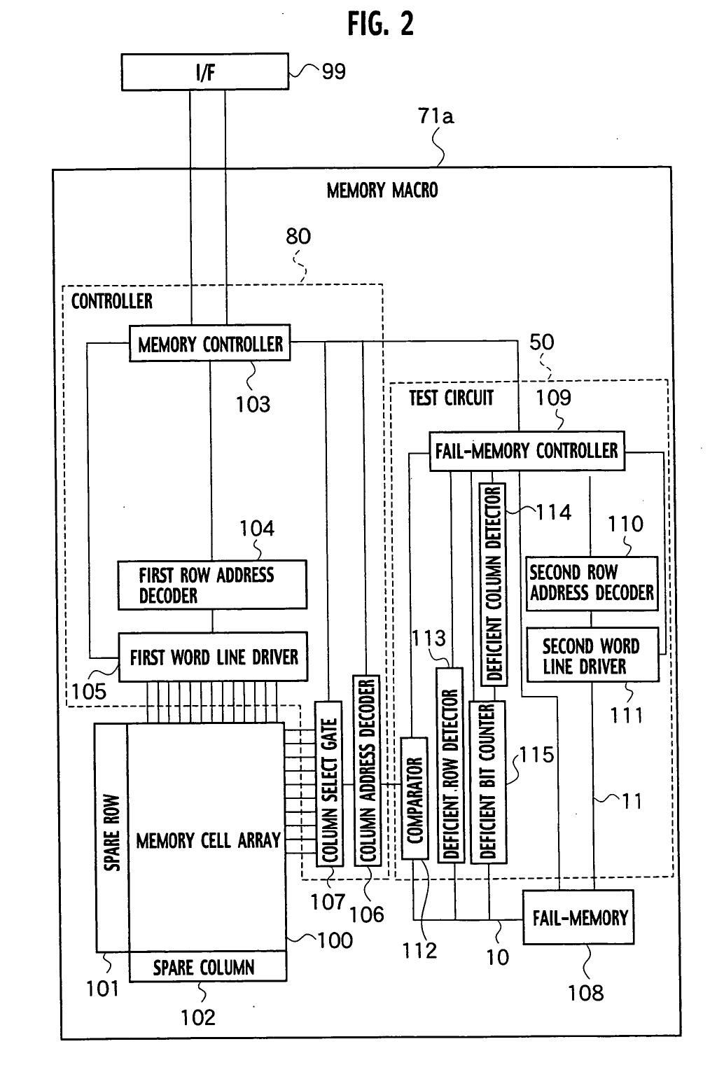

As shown in FIG. 2, the controller 80 includes a memory controller 103 connected to the interface 99, a first row address decoder 104 connected to the memory controller 103, a first word line driver 105 connected to the memory controller 103 and the first row address decoder 104, a column address decoder 106 connected to the memory controller 103 and test circuit 50, and a column select gate 107 connected to the memory controller 103 and the column address decoder 106.

The test circuit 50 includes a fail-memory controller 109 connected to the memory controller 103, a second row address decoder 110 connected to the fail-memory controller 109, a second word line driver 111 connected to the fail-memory controller 109 and the second row address decoder 110, a comparator 112 connected to the fail-memory 108 and the column address decoder 106, a deficient row detector 113 connected to the fail-memory 108 and the comparator 112, a deficient bit counter 115 connected to the fail-memory controller 109, the fail-memory 108 and the comparator 112, and a deficient column detector 114 connected to the fail-memory controller 109 and the deficient bit counter 115. The comparator 112, deficient row detector 113, and deficient bit counter 115 are connected to the fail-memory 108 via a bus 10. The second word line driver 111 is connected to the fail-memory 108 via a bus 11.

The memory cell array 100 is a matrix of memory cells, which are collocated at each intersection of rows and columns. The spare row 101 is a line of memory cells, which can be switched to a row in the memory cell array 100. The spare column 102 is a line of memory cells, which can be switched to a column in the memory cell array 100. The memory controller 103 receives an external signal from the tester 98 via the interface 99, and executes sequence control on all the circuits in the semiconductor memory 70. The memory controller 103 transmits data supplied from all the circuits in the semiconductor memory 70 via the interface 99 shown in FIG. 1. The memory controller 103 stores a value of a test vector generated by a pattern generator 97 in the memory cell array 100. The first row address decoder 104 decodes a first row address signal fed from the memory controller 103. The first word line driver 105 selects a row (word line) with respect to the first row address transmitted from the first row address decoder 104 together with a control signal from the memory controller 103. The column address decoder 106 decodes a column address signal transmitted from the memory controller 103. The column select gate 107 selects a column with respect to the column address transmitted from the column address decoder 106 together with a signal from the memory controller 103.

The fail-memory 108 stores data. The data is an address of a memory cell, row and column which should be changed because of errors. The stored data could be compressed. The fail-memory 108 transmits the data to the comparator 112, the deficient row detector 113, and the deficient bit detector 115 via the bus 10.

The fail-memory controller 109 operates each of the second row address decoder 110, the second word line driver 111, the comparator 112, the deficient row detector 113, the deficient column detector 114, the deficient bit counter 115, and the fail-memory 118 with the sequence control.

The fail-memory controller 109 operates the second row address decoder 110, the second word line driver 111, the comparator 112, the deficient row detector 113, the deficient column detector 114, the deficient bit counter 115, and the fail-memory 108 synthetically with the sequence control.

The fail-memory controller 109 retrieves the data for the row from the fail-memory 108, and determines whether the row selected by the first word line driver 105 has been already detected as the deficient row. The fail-memory controller 109 retrieves the data for the cell in the row from the fail-memory 108, and determines whether the cell selected by the first word line driver 105 has been already detected as a deficient bit. The fail-memory controller 109 feeds a signal to the fail-memory 108 to delete the data for the deficient bit in the deficient row and the deficient column. Moreover, the fail-memory controller 109 transmits the data received from the comparator 112, the deficient row detector 113, and the deficient column detector 114 to the memory controller 103.

The second row address decoder 110 decodes a second row address signal supplied from the fail-memory controller 109. The second word line driver 111 selects the row according to the second row address transmitted from the second row address decoder 110 together with a signal from the fail-memory controller 109.

The comparator 112 retrieves a value stored in the memory cell at the row address fed from the column address decoder 106, and compares the value with a value of the test vector supplied from the pattern generator 97. Then, when the value stored in the memory cell differs from the value of the test vector, the comparator 112 transmits the data for the deficient bit to the deficient row detector 113 and the deficient bit counter 115 according to the signal from the fail-memory controller 109, and stores the data in the fail-memory 108 as a deficient bit. The deficient bit is a memory cell which does not store data.

The deficient row detector 113 counts the number of the deficient bits in the row, compares the number of the deficient bits with a first criterion measure which is larger than 1.

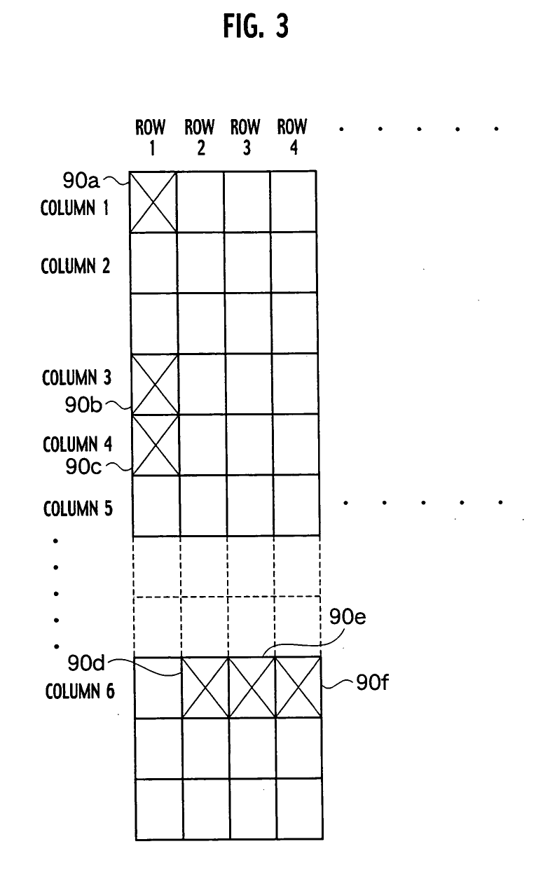

For example, the deficient row detector 113 sets a number of the spare columns as the first criterion measure. When the number of the deficient bits is larger than the first criterion measure, the deficient row detector 113 determines that the row is a deficient row, and supplies a row address of the deficient row to the fail-memory controller 109. As shown in FIG. 3, a row 1 has three deficient bits (memory cells 90a, 90b, and 90c). Then, assuming the number of the spare columns is 2, the first criterion measure is 2. Therefore, the deficient row detector 113 transmits the row address of the row 1 to the fail-memory controller 109 as a deficient row because the number of the deficient bits is larger than the first criterion measure.

The deficient counter 115 retrieves data for a plurality of rows from the fail-memory 108, counts the deficient bits in the same column of a plurality of rows, and transmits about result to the deficient column detector 114.

The deficient column detector 114 retrieves the result from the deficient bit counter 115, and compares the number of the deficient bits in the column with a second criterion measure. For example, the deficient column detector 114 sets the number of the spare rows as the second criterion measure. Then, when the number of the deficient bits in the same column is larger than the second criterion measure, the deficient column detector 114 determines the column as a deficient column and feeds the column address of the deficient column to the fail-memory controller 109. As shown in FIG. 3, the column 6 which is the column of a plurality of the rows (row 2, 3, 4) has the deficient bit (memory cells 90d, 90e, 90f). In this case, the deficient bit counter 115 determines that the number of deficient bits is 3. Then, assuming the number of the spare rows is 2, the deficient bit counter 115 sets 2 as the second criterion. Therefore, the deficient column detector 114 feeds the column address of column 6 as a deficient column to the fail-memory controller 109 because the number of deficient bits is larger than the second criterion.

As shown in FIG. 1, a system for testing a memory cell according to a first embodiment includes the tester 98, and semiconductor memory 70 set forth above.

The tester 98 includes the pattern generator 97, an address fail-memory 96, a compare-instruction unit 95, and a detect-instruction unit 94.

The pattern generator 97 generates the test vector and transmits the test vector to the memory controller 103 shown in FIG. 2 via the interface 99. The pattern generator 97 supplies the value of the test vector to the comparator 112 shown in FIG. 2 via the interface 99.

The address fail-memory 96 stores the data stored in the fail-memory 108. The compare-instruction unit 95 commands the comparator 112 to compare a value stored in a memory cell in a row of the memory cell array 100 with a value of the test vector. The compare-instruction unit 95 commands the comparator 112 to determine the memory cell as the deficient bit when the value stored in the memory cell differs from the value of the test vector. The detect-instruction unit 94 commands the deficient row detector 113 shown in FIG. 2 to compare number of a deficient bits in a row of the memory cell array 100 with the first criterion measure. The detect-instruction unit 94 commands the deficient row detector 113 to determine the row as a deficient row when the number of the deficient bits is larger than the first criterion. The detect-instruction unit 94 commands the fail-memory 108 to store the data for the deficient bit when the number of the deficient bits is not larger than the first criterion.

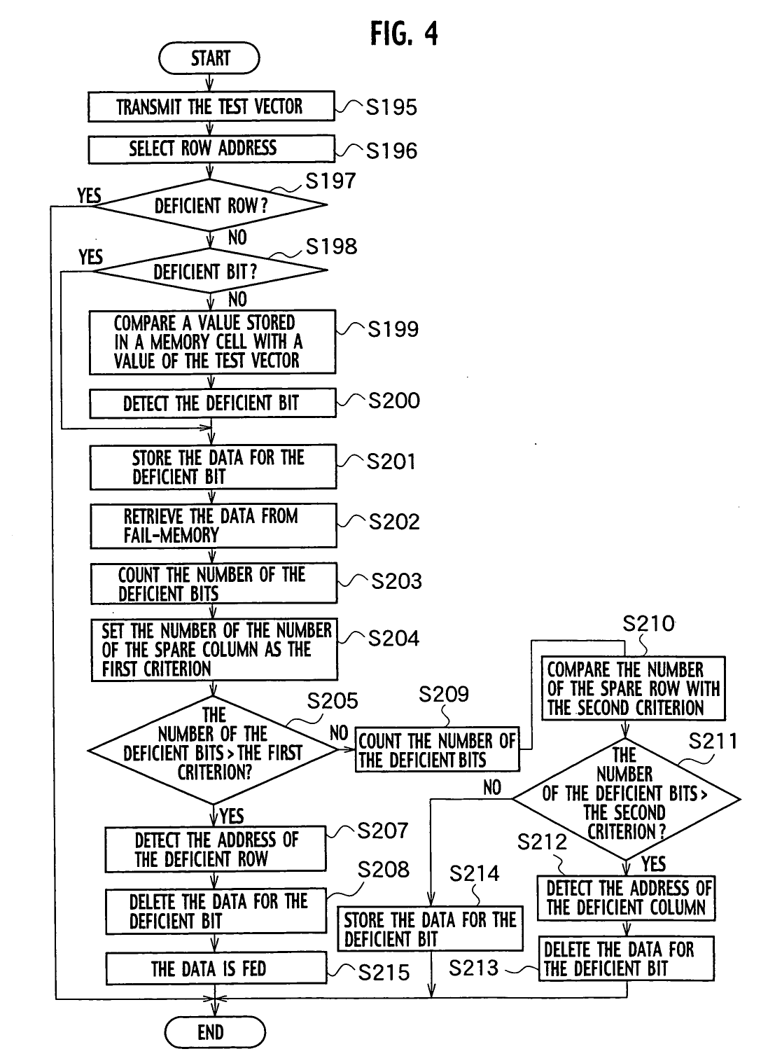

A method for testing a memory cell is shown in FIG. 4. Each of a memory macro 71a, 71b, 71c, 71d, or the like executes a method set forth below in parallel.

(a) In Step S195, the pattern generator 97 supplies the test vector to the memory cell array 100 via the memory controller 103. In Step S196, the first word line driver 105 shown in FIG. 2 selects a row in the memory cell array 100. In Step S197, the fail-memory controller 109 determines whether the row selected by the first word line driver 105 has already been determined as the deficient row. When the row has already been determined as the deficient row in Step S197, the row does not need to be determined again, and a next row is selected to determine whether the next row is deficient. When the row has not been determined as a deficient row in Step S197, the fail-memory controller 109 determines whether the memory cell in the row selected by the first word line driver 105 is already determined as the deficient bit in Step S198. When the memory cell is determined as a deficient bit in Step 198, a process of the method proceeds to Step S201. When the memory cell is not determined as a deficient bit in Step S198, then in Step S199, the comparator 112 retrieves the value stored in the memory cell in the row from the memory cell array 100, and compares the value with a value of the test vector generated by the pattern generator 97. When the value stored in the memory cell differs from the value of the test vector in Step S199, the comparator 112 determines the memory cell as a deficient bit in Step 200. Then in Step S201, an address of the bit is stored in the fail-memory 108 as data for the deficient bit.

(b) In Step S202, the deficient row detector 113 retrieves the data for a plurality of the rows in the memory cell array 100 from the fail-memory 108. In Step S203, the deficient row detector 113 counts the number of the deficient bits in the same row. In Step S204, the deficient row detector 113 sets the number of the spare columns 102 as the first criterion. In Step S205, the deficient row detector 113 compares the number of the deficient bits in the same row with the first criterion. When the number is larger than the first criterion in Step S205, then in Step S207, the deficient row detector 113 detects the row as a deficient row, and supplies the address of the row to the fail-memory 108 and fail-memory controller 109. In Step S208, the fail-memory controller 109 deletes the data for the deficient bit in the row from the fail-memory 108.

(c) When the number of the deficient bits is larger than the first criterion in Step S205, then in Step S209, the deficient bit counter 115 retrieves the data for the deficient bit from the fail-memory 108, and counts the number of the deficient bits in the same column.

(d) In Step S210, the deficient column detector 114 sets the number of the spare rows as the second criterion. In Step S211, the deficient column detector 114 retrieves the result of counting from the deficient bit counter 115, and compares the number of the deficient bits in the same column with the second criterion. When the number of the deficient bits is larger than the second criterion, then in Step S212, the deficient column detector 114 determines the deficient column, and feeds the address of the column to the fail-memory 108 and fail-memory controller 109. In Step S213, the fail-memory controller 109 deletes the data for the deficient bit in the column from the fail-memory 108.

(e) In Step S211, when the number of the deficient bits is not larger than the second criterion, then in Step S214, the data for the deficient bits is still stored in the fail-memory 108.

(f) In Step S 215, the data stored in the fail-memory 108 in Step S207, S212, and S214 is transmitted to the address fail-memory 96. Each of the memory macros 71a, 71b, 71c, 71d or the like feeds the data stored in each fail-memory to the address fail-memory 96 sequentially.

According to the first embodiment, the data for the deficient row and the deficient column are stored in the fail-memory 108, and the data for the deficient bit in the row and the column, which has a larger volume than the data for the deficient row and the deficient column, is deleted from the fail-memory 108. Therefore, the total volume of the data in the fail-memory 108 decreases to less than that of the prior art. A scale of the semiconductor memory 70 is minimized and dissipation of the semiconductor memory 70 is also minimized. The time for transmitting data to the external device is decreased and a total time for testing the memory cell is decreased.

Moreover, according to the first embodiment, each of the test circuits 50 in the each of the memory macros 71a, 71b, 71c, or the like tests the semiconductor memory 70. Accordingly, the total time for testing the memory cell is decreased by testing of a plurality of the test circuit. In particular, when N sections of the test circuits test the memory cell array 100 divided into N sections of the memory macros, the test time is 1/N times shorter than the one test circuit test.

According to the first embodiment, the deficient row detector 113 retrieves the data from fail-memory 108. However, the deficient row detector 113 may retrieves the data from the comparator 112. According to the first embodiment, the deficient row detector 113 sets the number of the spare columns as the first criterion. However, the deficient row detector 113 may set a number which whole integer larger than one to the number of spare column for the first criterion.

According to the first embodiment, the deficient column detector 114 retrieves the deficient data from the fail-memory 108. However, the deficient column detector 114 may retrieve the deficient data from the comparator 112. According to the first embodiment, the deficient column detector 114 sets number of the spare rows as the second criterion measure. However, the deficient column detector 114 may set a certain number which is larger than 1 and smaller than the number of the spare rows as the second criterion measure.

(Other Embodiments)

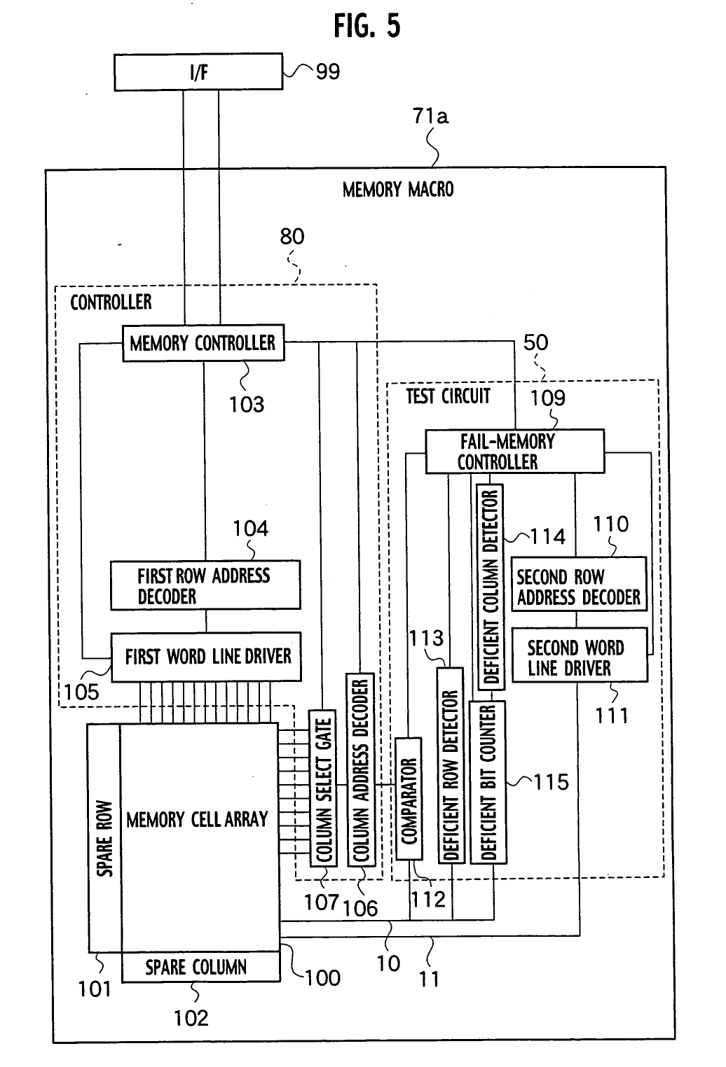

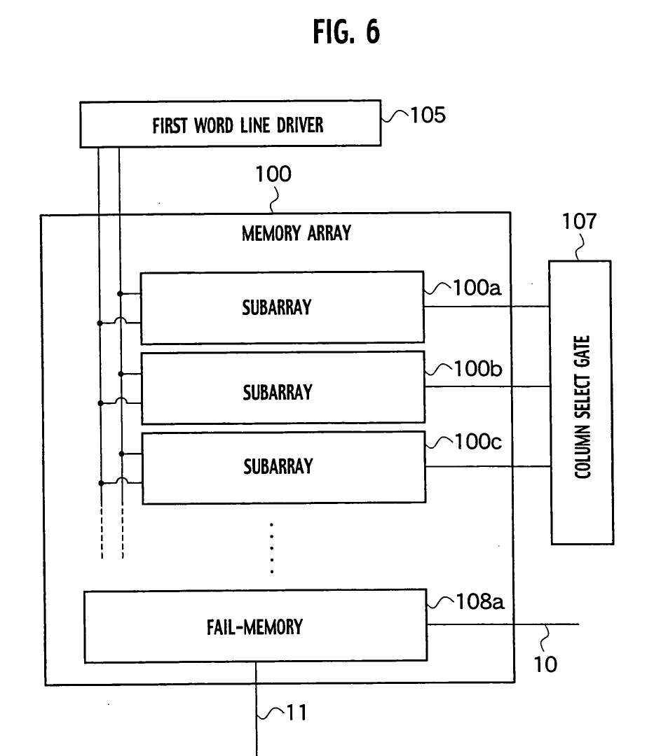

As shown in FIG. 6, the fail-memory 108a may comprise memory cells at certain area of the memory cell array 100. As shown in FIG. 5, the memory macro 71a includes the controller 80, the test circuit 50 connected to the controller 80, the memory cell array 100 connected to the controller 80, the spare row 101 connected to the memory cell array 100, and the spare column 102 connected to the memory cell array 100. As shown in FIG. 6, the memory cell array 100 includes sub arrays 100a, 100b, 100c and the like connected to the first word line driver 105 and column select gate 107, and the fail-memory 108a connected to the comparator 112 shown in FIG. 5, the deficient row line detector 113 shown in FIG. 5, and the deficient bit counter 115 shown in FIG. 5 via the bus 10, and connected to the second word line driver 111 via the bus 11. Each of the memory macro 71b, 71c, 71d and the like has similar parts as that of the memory macro 71a.

Each of the sub arrays 100a, 100b, 100c and the like is a matrix of memory cells, which are collocated at each intersection of rows and columns. The first word line driver 105 selects a row in the sub array 100a, 100b, 100c and the like with respect to the first row address transmitted from the first row address decoder 104 together with a control signal from the memory controller 103. The column select gate 107 selects a column in the sub array 100a, 100b, 100c and the like with respect to the column address fed from the column address decoder 106 together with a signal from the memory controller 103. The fail-memory 108a stores the data for the deficient bit, the deficient row, and deficient column. The comparator 112, the deficient row detector 113, and the deficient bit counter 115 retrieve the data from the fail-memory 108a.

The semiconductor memory is minimized because of the fail-memory 108a which common to the memory macros 100a, 100b, 100c and the like.

Various modifications will become possible for those skilled in the art after receiving the teachings of the present disclosure without departing from the scope thereof.

What is claimed is:

1. A semiconductor memory comprising:
a memory cell array defined by a matrix of memory cells collocated at each intersection of rows and columns of the memory cells;
a fail-memory configured to store data for a deficient bit, a deficient row, and deficient column in the memory cell array;
a comparator configured to transmit a test vector to the memory cells by scanning the rows, to compare a value stored in the memory cells with the value of the test vector, and to detect a memory cell as the deficient bit when the value stored in the memory cell differs from the value of the test vector; and
a deficient row detector configured to compare the number of deficient bits with a first criterion which is larger than one in the row, to detect an address of the row when the number of deficient bits is larger than the first criterion, and to store the data for the deficient bit when the number of deficient bits is not larger than the first criterion.

2. The semiconductor memory of claim 1, wherein the deficient row detector stores the address of the deficient row.

3. The semiconductor memory of claim 1, further comprising a spare column which replaces to the deficient column.

4. The semiconductor memory of claim 3, wherein the first criterion is the number of the spare column.

5. The semiconductor memory of claim 1, further comprising:
a deficient bit counter configured to count the number of deficient bits in the column based on the data for the deficient bit; and
a deficient column detector configured to compare the number of deficient bits in the column with a second criterion which is larger than one, and to detect an address of the column as the deficient column when the number of deficient bits in the column is larger than the second criterion.

6. The semiconductor memory of claim 5, further comprising a spare row which replaces to the deficient row.

7. The semiconductor memory of claim 6, wherein the second criterion is the number of the spare row.

8. The semiconductor memory of claim 1, wherein the memory cell array comprises a plurality of sub arrays which are divided of the memory cell array.

9. A system for testing a memory cell comprising:
a pattern generator configured to generate a test vector to a memory cell array which is a matrix of memory cells collocated at each intersection of rows and columns of the memory cells;
a compare-instruction unit configured to instruct the pattern generator to transmit the test vector to each of the memory cells by scanning a row, to instruct a semiconductor memory to compare a value stored in the memory cell with a value of the test vector, and instruct the semiconductor memory to detect the memory cell as a deficient bit when the value stored in the memory cell differs from the value of the test vector;
a detect-instruction unit configured to instruct the semiconductor memory to compare the number of deficient bits with a first criterion which is larger than one in the row, to instruct the semiconductor memory to detect an address of the row when the number of deficient bits is larger than the first criterion, and to instruct the semiconductor memory to store data for the deficient bit when the number of deficient bits is not larger than the first criterion; and
an address fail-memory configured to store the data for the address of the row.

10. A method for testing a memory cell in a plurality of memory macros, wherein:
transmitting the test vector to each of memory cells of each of a plurality of memory macros in a memory cell array defined by a matrix of the memory cells collocated at each intersection of rows and columns of the memory cells;
comparing a value stored in the memory cells of each of the memory macros with a value of the test vector;
detecting the memory cells of each of the memory macros as a deficient bit when the value stored in the memory cells differ from the value of the test vector;
counting the number of deficient bits in the row of each of the memory macros;
comparing the number of deficient bits in the row of each of the memory macros with first criterion which is larger than one;
detecting an address of the row of each of the memory macros as the deficient row when the number of deficient bits in the row is larger than the first criterion;
storing data for the deficient bits of each of the memory macros when the number of deficient bits is not larger than the first criterion; and
transmitting the data of each of the memory macros stored to a tester sequentially.

11. The method of claim 10, further comprising:
counting the number of deficient bits in the column of each of the memory macros based on the data for the deficient bits;
comparing the number of deficient bits in the column of each of the memory macros with a second criterion which is larger than one;
detecting an address of the column of each of the memory macros as the deficient column when the number of deficient bits in the column is larger than the second criterion; and
transmitting the data for the address of the column of each of the memory macros to a tester sequentially.
